(19) United States
(12) Patent Application Publication
(10) Pub. No.: US 2002/0060594 A1
(43) Pub. Date: May 23, 2002

(54) METHOD AND APPARATUS FOR A HIGH FREQUENCY, LOW POWER CLOCK DISTRIBUTION WITHIN A VLSI CHIP

(76) Inventors: DANIEL LAWRENCE STASIAK, ROCHESTER, MN (US); JAMES DAVID STROM, ROCHESTER, MN (US); JEFF V. TRAN, ROCHESTER, MN (US)

Correspondence Address: JAMES R. NOCK, IBM CORPORATION- DEPT. 917, 3605 HIGHWAY 52 NORTH, ROCHESTER,, MN, 55901, US

(21) Appl. No.: 09/454,314

(22) Filed: Dec. 3, 1999

(51) Int. Cl. H03K 19/00

(52) U.S. Cl. 327/295

(57) ABSTRACT

A method and apparatus are provided for a high frequency, low power clock distribution within a very large scale integrated (VLSI) circuit chip. The apparatus for a high frequency, low power clock distribution within a very large scale integrated (VLSI) circuit chip includes a first clock circuit generating a first clock signal. A first level inverter is coupled to the first clock circuit receiving the first clock signal. A clock multiplier is coupled to the first level inverter, generating a multiplied clock signal. A plurality of inverters are coupled to the clock multiplier for driving logic circuits within the VLSI circuit chip at the multiplied clock signal.

### FIELD OF THE INVENTION

The present invention relates generally to the data processing field, and more particularly, relates to a method and apparatus for a high frequency, low power clock distribution within a very large scale integrated (VLSI) circuit chip.

### DESCRIPTION OF THE RELATED ART

VLSI chips use clock signals to control latches, arrays, input/output (IO) and circuits. The clock frequency chosen for the VLSI chip gives designers a limit of an amount of logic that can fit between latches. To give these designers an early start and a box to work within, the clock frequency is chosen early in the chip design before the clock network is complete. Actually, the clock network is not completed until the chip logic is finished and all latch locations are known. Therefore, to increase the quality of the chip timing, the following requirements of the clock distribution network are desired:

1. Zero Skew;

2. Zero Jitter;

3. 50/50 Duty Cycle;

4. Low Power;

4a. Low number of circuit levels to lower number of circuits that switch at clock speed;

4b. Sharp Rise and Fall Times;

4c. Gate clock when logic is not used; and

5. Low over and under shoot.

The first three requirements, Zero Skew; Zero Jitter; and 50/50 Duty Cycle give designers at the chip level down to the circuit level the same clock signal to work with in timing. This simplifies the chip timing methodology and shortens chip design cycles.

Clock Skew equal to zero means all clock sinks over the entire chip receive the clock signal at the same instant in time. In other words, the delay through the clock distribution network is uniform for all clock signal destinations. Jitter equal to zero and 50/50 duty cycle refers to the shape of the clock signal remaining consistent from cycle to cycle. There is no drifting of the transition points. So for a 1 GHz clock example, each designer can assume the clock will arrive at 0 ps, be low for 400 ps, transition from GND to VDD in 100 ps, stay high for 400 ps and transition from VDD to GND in 100 ps. Each following cycle will also be the same with no variation.

As a VLSI chip becomes larger with more circuits, high power usage becomes more a problem. For one known chip, the clock network consumed 50% of the chip's total 150 Watts to distribute the clock. Lowering the power consumption of the clock network is more difficult as clock frequencies increase but any power savings in the clock network could significantly lower a VLSI chip's total power. One known technique used to lower the clock network's power usage is to reduce the number of circuits that drive the clock signal high and low every cycle. Less circuits switching at clock speed results in less power usage. Designing clock networks so the clock signal has short rise and fall times reduces shoot through current and lowers power usage. To lower the total clock network power usage, a balance between fast rise and fall times and less clock rebuffering must be reached. Another technique to lower power usage is gating clock off when logic is not used.

As clock frequencies increase, the clock network becomes more inductive causing over and under shoots with the clock signal. The danger of over and under shoots are that when these extra transitions are large enough to be mistakenly recognized as another clock transition. This could create hardware errors.

Referring to FIG. 1, a prior art clock distribution arrangement to distribute a clock signal inside a VLSI chip is shown. This clock tree style is called an H tree clock distribution because the clock wiring resembles the letter H to balance the wire delay across the chip. A phase locked loop (PLL) circuit generates the clock at the chip frequency, in this case 1 GHz, and sends the clock to the large central inverter 1. The inverter 1 drives four second level inverters 2A, 2B, 2C, and 2D, at the same frequency of 1 GHz. Each second level inverter 2A, 2B, 2C, and 2D drives eight third level inverters. For example, inverter 2C drives inverters 3I, 3J, 3K, 3L, 3M, 3N, 3O and 3P. The final inverters of the H tree then drive logic circuits within the VLSI design. Notice that the first level inverter is very large to drive the long wide wire. As the network fans out, inverters and wires become smaller.

For the prior art arrangement of FIG. 1, skew is low by balancing the clock network. Jitter is controlled by the PLL. Across chip transistor length variations (ACLV) along with N-channel field effect transistor (NFET) to P-channel field effect transistor (PFET) strength variations, creates some skew and jitter regardless of wiring. Clock wires are generally thicker than signal wires to increase rise and fall times. Making the wires thicker creates more capacitance to charge and discharge at the clock frequency which raises power usage. Notice in FIG. 1, wire #1 is thicker than wire #2 which is thicker than wire #3.

A need exists for an improved method and apparatus for a high frequency, low power clock distribution within a very large scale integrated (VLSI) circuit chip.

### SUMMARY OF THE INVENTION

A principal object of the present invention is to provide a method and apparatus for a high frequency, low power clock distribution within a very large scale integrated (VLSI) circuit chip. Other important objects of the present invention are to provide such a method and apparatus for a high frequency, low power clock distribution within a very large scale integrated (VLSI) circuit chip substantially without negative effect and that overcome many of the disadvantages of prior art arrangements.

In brief, a method and apparatus are provided for a high frequency, low power clock distribution within a very large scale integrated (VLSI) circuit chip. The apparatus for a high frequency, low power clock distribution within a very large scale integrated (VLSI) circuit chip includes a first clock circuit generating a first clock signal. A first level inverter is coupled to the first clock circuit receiving the first clock signal. A clock multiplier is coupled to the first level inverter, generating a multiplied clock signal. A plurality of inverters are coupled to the clock multiplier for driving logic circuits within the VLSI circuit chip.

### BRIEF DESCRIPTION OF THE DRAWINGS

The present invention together with the above and other objects and advantages may best be understood from the following detailed description of the preferred embodiments of the invention illustrated in the drawings, wherein:

FIG. 1 is a prior art clock distribution arrangement within a VLSI chip;

FIG. 2 is a schematic diagram representation of a clock distribution arrangement within a VLSI chip in accordance with the preferred embodiment; and

FIG. 3 is a schematic diagram representation of an alternative clock distribution arrangement within a VLSI chip in accordance with the preferred embodiment.

### DETAILED DESCRIPTION OF THE PREFERRED EMBODIMENTS

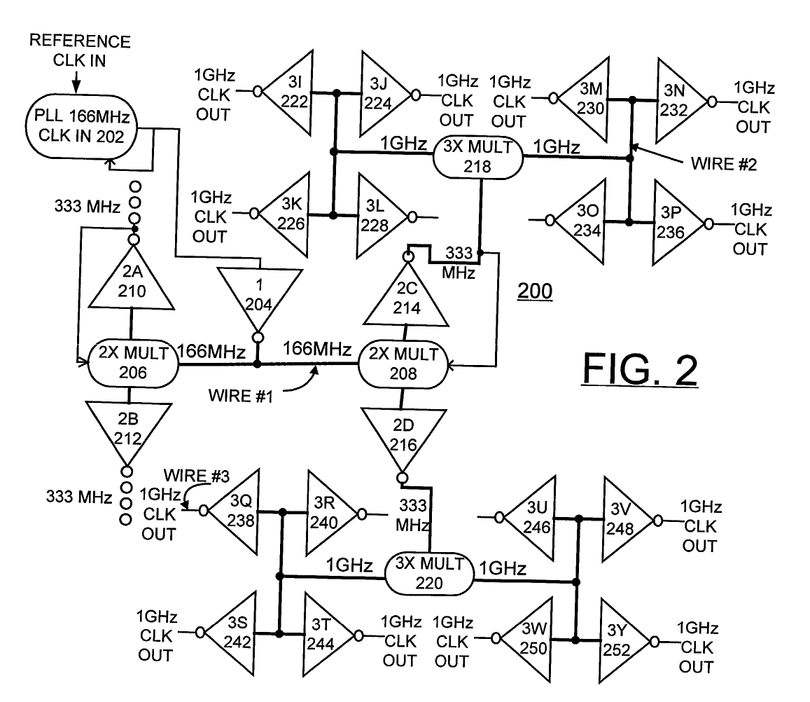

Having reference now to the drawings, in FIG. 2, there is shown a clock distribution arrangement within a VLSI chip in accordance with the preferred embodiment generally designated by the reference character 200. As shown in FIG. 2, clock distribution arrangement 200 is shown as an H tree clock network; however, it should be understood that the present invention is not limited to the H tree distribution. For example, the present invention can be used with clock grids and other distribution methods within a VLSI chip. The VLSI chip in FIG. 2 has a clock frequency of 1 GHz. A phase locked loop (PLL) circuit 202 generates a 166.66 MHz clock and sends the clock to a large central inverter 204. The inverter 204 drives the clock to a pair of clock multipliers 206 and 208. Each first level clock multiplier 206 and 208 multiplies the clock input by two and generates a 333.33 MHz output clock. The first level clock multipliers 206 and 208 respectively drive a pair of second level inverters 210, 212 and 214, 216. Each of the second level inverters 210, 212 and 214, 216 respectively drive the 333.33 MHz output clock to a second level clock multiplier (two shown) 218, 220. Each second level clock multiplier 218, 220 is a 3× clock multiplier that receives the 333.33 MHz clock input and drives eight third level inverters (sixteen shown) 222, 224, 226, 228, 230, 232, 234, 236 and 238, 240, 242, 244, 246, 248, 250, 252 at 1 GHz. The final third level inverters 222, 224, 226, 228, 230, 232, 234, 236 and :238, 240, 242, 244, 246, 248, 250, 252 of the H clock distribution tree 200 then drive logic circuits within the VLSI design at the chip speed of 1 GHz.

In accordance with features of the invention, the clock multipliers 206, 208, 218, 220 are designed using phase locked loops (PLLs) or digital multipliers (DMs). These designs lock on with feedback so no phase shifting occurs and a balanced delay through the clock network is maintained. Low multipliers are used to keep internal PLL jitter down. Lower multipliers, such as 2× or 3×, typically produce less jitter than larger multipliers, such as 10×. Also the multipliers 206, 208, 218, 220 can be designed with longer than minimum effective length transistors to lower process variation effects across the chip.

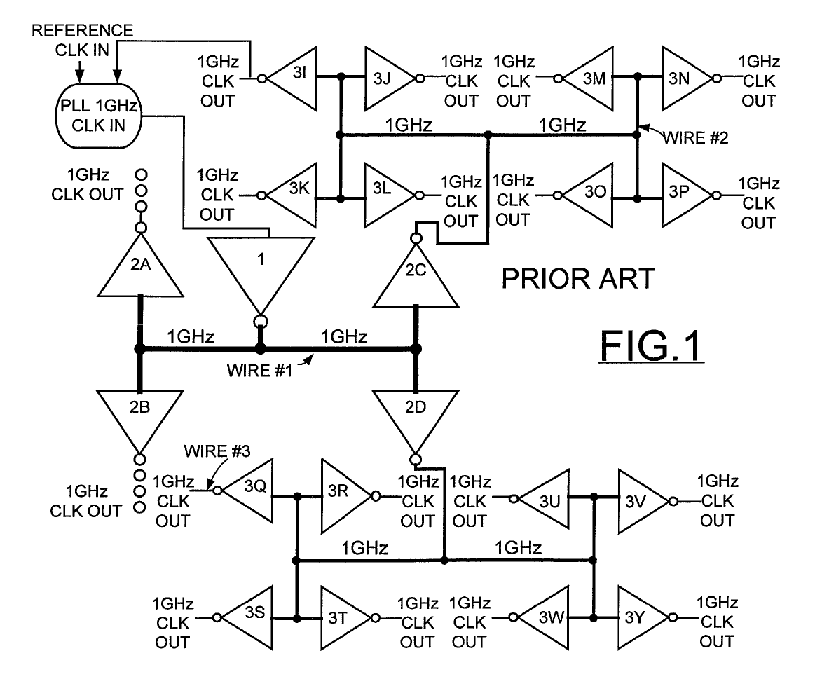

In accordance with features of the invention, the clock distribution arrangement 200 broadcasts a clock signal throughout a VLSI chip using less power since the larger inverters and wider wires in the early part of the clock network 200 as compared to the prior art arrangement of FIG. 1 are smaller and are switched at a lower rate. Notice that wire #1 of FIG. 2 is thinner than wire #1 of FIG. 1. The shorter and thinner wires at the end of the clock tree distribution network 200, wires #3 have lower capacitance and inductive noise and can handle the higher frequencies with less problems. In accordance with the preferred embodiment, clock distribution arrangement 200 has only these shorter and thinner wires running at the high chip cycle times. In addition to power savings, clock distribution arrangement 200 of the preferred embodiment allows clock distribution over a larger VLSI chip since sending the clock signal at the lower frequency is easier. Clock distribution arrangement 200 results in lower electromagnetic signals or radiation from the chip than conventional arrangements such as shown in FIG. 1.

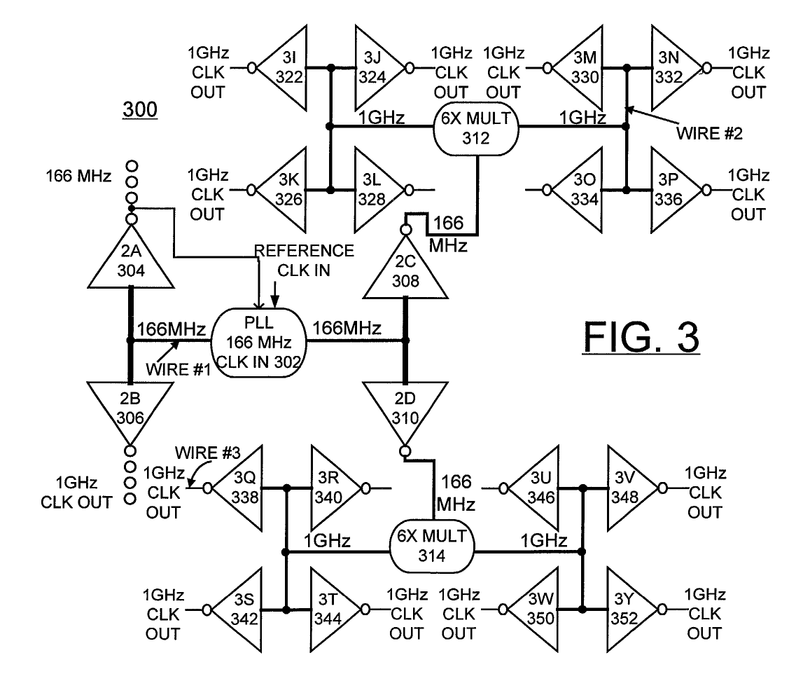

Referring to FIG. 3, another embodiment of the invention is shown in accordance with the preferred embodiment generally designated by the reference character 300. As in clock tree distribution network 200 of FIG. 2, clock distribution tree 300 drives logic circuits within the VLSI design at the chip speed of 1 GHz. A PLL circuit 302 generates a 166.66 MHz clock and sends the clock to four rebuffering inverters 304, 306, 308, 310. Each inverter 304, 306, 308, 310 feeds a second level clock multiplier (two shown) 312 and 314. Each second level clock multipliers 312, 314 is a 6× clock multiplier. Each second level clock multipliers 312, 314 drives eight third level inverters 322, 324, 326, 328, 330, 332, 334, 336 and 338, 340, 342, 344, 346, 348, 350, 352 at 1 GHz. The final third level inverters 322, 324, 326, 328, 330, 332, 334, 336 and 338, 340, 342, 344, 346, 348, 350, 352 of the H clock distribution tree 300 then drive logic circuits within the VLSI design at the chip speed of 1 GHz.

It should be understood that principles of the present invention apply where the network 300 of FIG. 3 has a 6× second level clock multiplier for either each Functional Unit or a square area of the chip. The clock network 300 can be broken up into Functional Branches instead of chip area branches.

It should be understood that the 6× clock multiplication is arbitrarily shown to illustrate the invention. It should be understood that various other combinations could be used in accordance with principles of the present invention. For example, a 100 MHz clock input and a 10× multiplier, or a 200 MHz clock input and 5× multiplier could be used in accordance with principles of the present invention.

While the present invention has been described with reference to the details of the embodiments of the invention shown in the drawing, these details are not intended to limit the scope of the invention as claimed in the appended claims.

What is claimed is:

1. Apparatus for a high frequency, low power clock distribution within a very large scale integrated (VLSI) circuit chip comprising:
a first clock circuit generating a first clock signal;
a first level inverter coupled to said first clock circuit receiving said first clock signal;
a clock multiplier coupled to said first level inverter, said clock multiplier generating a multiplied clock signal; and
a plurality of inverters coupled to said clock multiplier for driving logic circuits within the VLSI circuit chip at said multiplied clock signal.

2. Apparatus for a high frequency, low power clock distribution within a very large scale integrated (VLSI) circuit chip as recited in claim 1 wherein said first clock circuit comprises a phase locked loop (PLL) circuit.

3. Apparatus for a high frequency, low power clock distribution within a very large scale integrated (VLSI) circuit chip as recited in claim 1 wherein said clock multiplier comprises a first clock multiplier and a second clock multiplier; said first clock multiplier coupled to said second clock multiplier by an inverter.

4. Apparatus for a high frequency, low power clock distribution within a very large scale integrated (VLSI) circuit chip as recited in claim 1 wherein said clock multiplier comprises a phase locked loop (PLL).

5. Apparatus for a high frequency, low power clock distribution within a very large scale integrated (VLSI) circuit chip as recited in claim 1 wherein said clock multiplier comprises a digital multiplier (DM).

6. Apparatus for a high frequency, low power clock distribution within a very large scale integrated (VLSI) circuit chip as recited in claim 1 wherein said clock multiplier has a set multiplier value in a range between two and ten.

7. Apparatus for a high frequency, low power clock distribution within a very large scale integrated (VLSI) circuit chip as recited in claim 3 wherein said first clock multiplier and said second clock multiplier have a set multiplier value in a range between two and five.

8. Apparatus for a high frequency, low power clock distribution within a very large scale integrated (VLSI) circuit chip as recited in claim 1 wherein said first clock signal has a lower frequency than said multiplied clock signal.

9. Apparatus for a high frequency, low power clock distribution within a very large scale integrated (VLSI) circuit chip as recited in claim 1 wherein said first clock signal has a set frequency in a range between 100 MHz and 200 MHz.

10. Apparatus for a high frequency, low power clock distribution within a very large scale integrated (VLSI) circuit chip as recited in claim 1 wherein said multiplied clock signal has a frequency of about 1 GHz.

11. A method for implementing a high frequency, low power clock distribution within a very large scale integrated (VLSI) circuit chip comprising the steps of:
generating a first clock signal, utilizing a first clock circuit;
coupling a first level inverter to said first clock circuit receiving said first clock signal;
generating a multiplied clock signal, utilizing a clock multiplier coupled to said first level inverter; and
providing a plurality of inverters coupled to said clock multiplier for driving logic circuits within the VLSI circuit chip at said multiplied clock signal.

12. Apparatus for a high frequency, low power clock distribution within a very large scale integrated (VLSI) circuit chip comprising:
a first clock circuit generating a first clock signal;
a first level inverter coupled to said first clock circuit receiving said first clock signal;
a first clock multiplier coupled to said first level inverter, said first clock multiplier generating a multiplied clock signal;
a second clock multiplier coupled to said first clock multiplier, said second clock multiplier generating a second multiplied clock signal; and
a plurality of inverters coupled to said second clock multiplier for driving logic circuits within the VLSI circuit chip at said second multiplied clock signal.
